(19) United States
(12) Patent Application Publication
(10) Pub. No.: US 2010/0180936 A1
(43) Pub. Date: Jul. 22, 2010

(54) Multijunction solar cell

(75) Inventor: Taek Kim, Seongnam-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/585,491

(22) Filed: Sep. 16, 2009

(30) Foreign Application Priority Data
Jan. 19, 2009 (KR) 10-2009-0004199

(51) Int. Cl. H01L 31/00

(52) U.S. Cl. 136/255

(57) ABSTRACT

A multijunction solar cell according to example embodiments may include a plurality of sub cells, each sub cell having a different band gap energy. At least one of the plurality of sub cells may be a GaAsN sub cell having alternately stacked first layers and second layers. The first layers may be formed of GaAsₓN₁₋ₓ (0<x<1), and second layers may be formed of GaₓIn₁₋ₓN_{y}As_{1-y} (0<x<1, 0≦y<1).

### CROSS-REFERENCE TO RELATED APPLICATION

This application claims priority under 35 U.S.C. §119 to Korean Patent Application No. 10-2009-0004199, filed on Jan. 19, 2009 with the Korean Intellectual Property Office, the disclosure of which is incorporated herein in its entirety by reference.

### BACKGROUND

1. Field

Example embodiments relate to a multijunction solar cell manufactured using a semiconductor material.

2. Description of the Related Art

Solar cells are photoelectric converting devices that may be used to convert solar energy into electricity. Solar cells have been hailed as an alternative energy source of the future.

Based on the materials employed in the solar cells, solar cells may be classified as a silicon semiconductor type or a compound semiconductor type. The solar cells classified as a silicon semiconductor type may be further classified as a crystallization system or an amorphous system.

Solar cells absorb energy above the band gap energy from solar light to generate electricity. When solar light having a relatively wide spectrum is photoelectrically converted in single junction solar cells, higher thermalization loss occurs. Although light having higher energy and a shorter wavelength excites holes in a semiconductor to a higher energy level, the carrier life time in an excitation state is relatively short. As a result, energy is emitted by heat and a voltage is generated after the energy level falls to a conduction band. Thus, the thermalization loss indicates a reduction in the efficiency of photoelectrical conversion.

### SUMMARY

Example embodiments relate to a multijunction solar cell having reduced crystalline defects and higher photoelectrical conversion efficiency. A multijunction solar cell according to example embodiments may include a plurality of sub cells, each sub cell having a different band gap energy, wherein at least one of the plurality of sub cells is a GaAsN sub cell having alternately stacked first layers and second layers, the first layers formed of GaAsₓN₁₋ₓ(0<x<1) and second layers formed of GaₓIn₁₋ₓN_{y}As_{1-y} (0<x<1, 0≦y<1). The plurality of sub cells in the multijunction solar cell may be four or more.

The second layers may be formed of GaₓIn₁₋ₓN_{y}As_{1-y} (0<x<1, 0≦y<0.5). The N constituent of GaₓIn₁₋ₓN_{y}As_{1-y} (0<x<1, 0≦y<1) may be determined so as to provide a lattice constant for offsetting the strain caused by the GaAsₓN₁₋ₓ (0<x<1). The band gap energy of GaₓIn₁₋ₓN_{y}As_{1-y} (0<x<1, 0≦y<1) and the band gap energy of GaAsₓN₁₋ₓ(0<x<1) may form a multi quantum well structure. The band gap energy of GaₓIn₁₋ₓN_{y}As_{1-y} (0<x<1, 0≦y<1) may be higher or lower than the band gap energy of GaAsₓN₁₋ₓ (0<x<1). The GaAsN sub cell may have a thickness of about 0.1 um to about 5 um.

The plurality of sub cells may include a first sub cell formed of Ge, and the GaAsN sub cell may be a second sub cell disposed on the first sub cell. The multijunction solar cell may further include a sub cell formed of InₓGa₁₋ₓAs (0<x<1), InₓGa₁₋ₓP (0<x<1), In_{1-x-y}GaₓAl_{y}P (0≦x<1, 0≦y<1, 0≦x+y<1), AlₓGa₁₋ₓAs (0<x≦1), or combinations thereof on the GaAsN sub cell. For instance, the multijunction solar cell may further include a third sub cell formed of InₓGa₁₋ₓAs (0<x<1) on the GaAsN sub cell. Additionally, the multijunction solar cell may include a fourth sub cell formed of InₓGa₁₋ₓP (0<x<1) on the third sub cell.

The GaAsN sub cell may have a p-n junction structure or a p-i-n junction structure. The multijunction solar cell may further include cladding layers formed of GaAs, AlGaAs, or InGaAlP on the uppermost layer and the lowermost layer of the GaAsN sub cell.

### BRIEF DESCRIPTION OF THE DRAWINGS

The above and/or other aspects of example embodiments may become apparent and more readily appreciated when the following detailed description is taken in conjunction with the accompanying drawings of which:

FIG. 1 is a cross-sectional view of a multijunction solar cell according to example embodiments;

FIG. 2 is a cross-sectional view of a GaAsN sub cell employed in the multijunction solar cell of FIG. 1;

FIG. 3 is a graph illustrating band gap energies and lattice constants of various Group III-V semiconductor materials;

FIG. 4 is a graph illustrating ranges of band gap energies and lattice constants of various Group III-V semiconductor materials employed in the GaAsN sub cell of FIG. 2;

FIG. 5 is a diagram illustrating the GaAsN sub cell of FIG. 2 compensating for strain;

FIGS. 6 through 9 are cross-sectional views of various examples of GaAsN sub cells employed in the multijunction solar cell of FIG. 1; and

FIGS. 10A through 11B are band gap diagrams of the GaAsN sub cells of FIGS. 6 through 9.

### DETAILED DESCRIPTION

It will be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on,” “directly connected to,” or “directly coupled to” another element or layer, there are no intervening elements or layers present. Like numbers refer to like elements throughout the specification. As used herein, the term “and/or” includes any and all combinations of one or more of the associated listed items.

It will be understood that, although the terms first, second, third, etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, e.g., “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or featureS would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

The terminology used herein is for the purpose of describing various embodiments only and is not intended to be limiting of example embodiments. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art. It will be further understood that terms, including those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be described more fully with reference to the accompanying drawings. In the drawings, like reference numerals denote like elements, and the sizes and/or thicknesses of layers and/or regions may have been exaggerated for clarity.

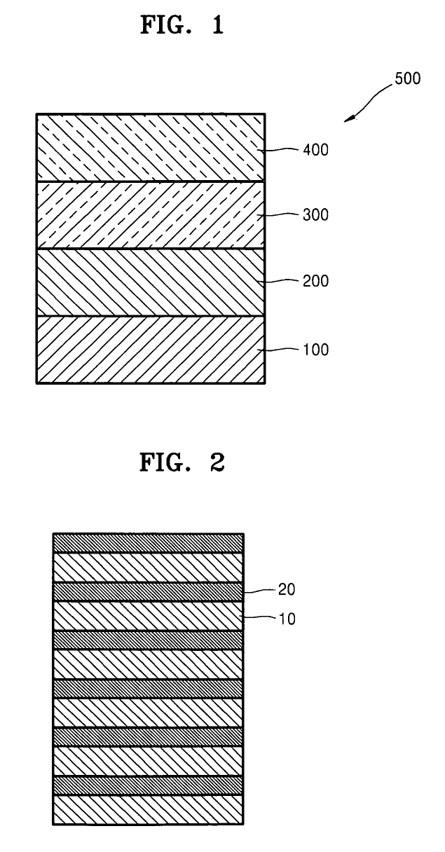

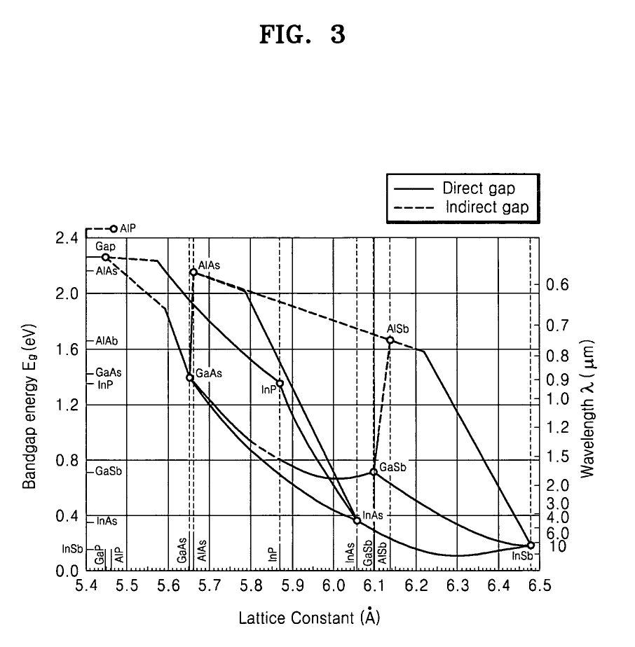

FIG. 1 is a cross-sectional view of a multijunction solar cell 500 according to example embodiments, and FIG. 2 is a cross-sectional view of a GaAsN sub cell employed in the multijunction solar cell 500 of FIG. 1. The multijunction solar cell 500 may be used to increase photoelectrical conversion efficiency and may include a plurality of sub cells formed of materials each having a different band gap energy to separately absorb the solar spectrum.

Referring to FIG. 1, the multijunction solar cell 500 may include four sub cells: a first sub cell 100, a second sub cell 200, a third sub cell 300, and a fourth sub cell 400. Alternatively, the multijunction solar cell 500 may include more than four sub cells. The first through fourth sub cells 100, 200, 300, and 400, respectively include semiconductor materials each having a different band gap energy E_{g} and may be formed with a p-n junction structure or a p-i-n junction structure. The first through fourth sub cells 100, 200, 300, and 400 may be connected to each other by a tunnel junction structure based on a principle in which current flows by combining electrons included in a conduction band of one sub cell with electron holes included in another sub cell using tunneling.

When solar light having an energy distribution of about 0.6 eV to about 6 eV is incident on the top surface of the multijunction solar cell 500, each of the first through fourth sub cells 100, 200, 300, and 400 may absorb solar light having a higher energy than band gap energies of the first through fourth sub cells 100, 200, 300, and 400. For example, when band gap energies of the first through fourth sub cells 100, 200, 300, and 400 are respectively E_{g1}, E_{g2}, E_{g3}, and E_{g4} (where E_{g1}<E_{g2}<E_{g3}<E_{g4}), the fourth sub cell 400 absorbs solar light having a higher energy than E_{g4} from the incident solar light Eₛ, the third sub cell 300 absorbs solar light in the range of E_{g3}<Eₛ≦E_{g4} from the incident solar light Eₛ, the second sub cell 200 absorbs solar light in the range of E_{g2}<Eₛ≦E_{g3}, and the first sub cell 100 absorbs solar light in the range of E_{g1}<Eₛ≦E_{g2}. The electrons and electron holes excited in each sub cell by the absorbed energy are moved by an electric field formed at a PN junction part, thus generating current flow.

The efficiency of the multijunction solar cell 500 theoretically increases as the number of sub cells increases. However, to increase the number of sub cells to thus increase the efficiency of the multijunction solar cell 500, the relationship between the lattice matching of adjacent sub cells and the band gap energies of the sub cells should be satisfied. The multijunction solar cell 500 may employ the GaAsN sub cell as at least one of the first through fourth sub cells 100, 200, 300, and 400.

For example, the first sub cell 100 may be formed of Ge, and the second sub cell 200 may be formed as a GaAsN sub cell. The third sub cell 300 and the fourth sub cell 400 are lattice matched and may be formed of a material selected from the group consisting of InₓGa₁₋ₓAs (0<x<1) (hereinafter, referred to as InGaAs), InₓGa₁₋ₓP (0<x<1) (hereinafter, referred to as InGaP), In_{1-x-y}GaₓAl_{y}P (0≦x<1, 0≦y<1, 0≦x+y<1) (hereinafter, referred to as In(Ga)(Al)P), AlₓGa₁₋ₓAs (0<x≦1) (hereinafter, referred to as Al(Ga)As), and combinations thereof. Also, the band gap energy of the fourth sub cell 400 may be selected to be larger than the band gap energy of the third sub cell 300. The third sub cell 300 may be formed of InGaAs, and the fourth sub cell 400 may be formed of InGaP.

As illustrated in FIG. 2, the GaAsN sub cell may have a structure in which first layers 10, formed of GaAsₓN₁₋ₓ (0<x<1), and second layers 20, formed of GaₓIn₁₋ₓN_{y}As_{1-y} (0<x<1, 0≦y<1), are alternately stacked. Hereinafter, GaAsₓN₁₋ₓ (0<x<1) may be represented by GaAsN, and GaₓIn₁₋ₓN_{y}As_{1-y} (0<x<1, 0≦y<1) may be represented by GaIn(N)As. The individual thickness and the number of layers may be coordinated such that the total thickness of the GaAsN sub cell is about 0.1 um to about 5 um.

An N composition ratio of GaIn(N)As, which may be the material for forming the second layer 20, may be determined to have a lattice constant for offsetting the strain generated as a result of the GaAsN. A more detailed discussion will be subsequently provided. The N content may be less than that of As. For example, the N content may be as expressed in Ga₁₋ₙN_{y}As_{1-y} (0≦y<0.5). The band gap energy of GaIn(N)As may be higher or lower than that of GaAsN. In addition, the second layer 20 may be formed to have smaller thickness than that of the first layer 10, and the band gap energy of GalnN_{y}As_{1-y} (0≦y<1) of the second layer 20 may be nearly the same as the band gap energy of GaAsN of the first layer 10.

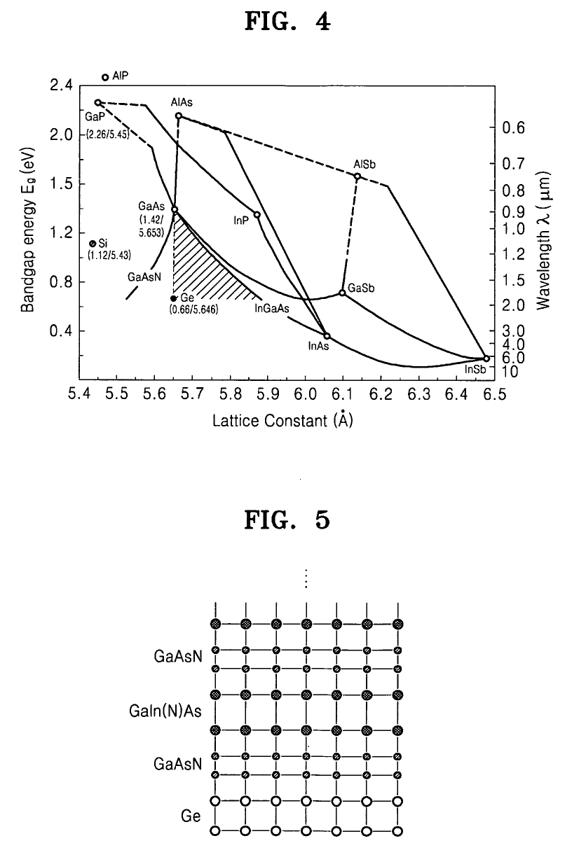

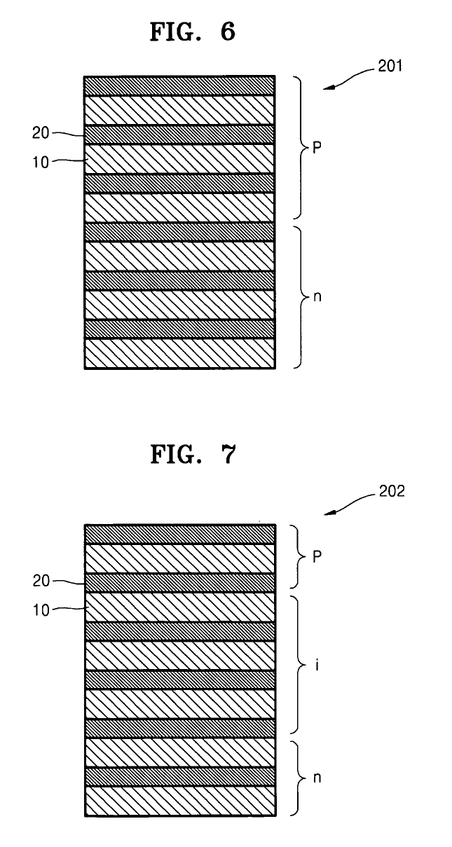

Hereinafter, the structure of the multijunction solar cell 500 and the GaAsN sub cell will be described with reference to FIGS. 3 through 5. FIG. 3 is a graph illustrating the band gap energies and lattice constants of various Group III-V semiconductor materials. FIG. 4 is a graph illustrating the ranges of band gap energies and lattice constants of various Group III-V semiconductor materials employed in the GaAsN sub cell of FIG. 2.

To efficiently absorb the relatively wide energy distribution of solar light, the difference in band gap energies between the first sub cell 100 and the fourth sub cell 400 is increased, and materials having an appropriate band gap energy interval may be interposed between the first sub cell 100 and the fourth sub cell 400. Energy band gap interval and lattice matching may be considered.

Referring to FIGS. 3 and 4, with regard to lattice matching with GaAs or Ge, which are generally used for substrate materials, materials having band gap energies in the range of about 1.2 eV to about 2.2 eV exist but materials having band gap energies below 1.2 eV do not exist. For example, when Ge having a band gap energy of about 0.7 eV is employed in the first sub cell 100, InGaAs, InGaP, In(Ga)(Al)P, and/or Al(Ga)As may be selected and each composition ratio may be adjusted to form the sub cells that lattice match with Ge. In this case, the band gap energy may have a value larger than about 1.2 eV. A new material may be formed when a relatively small amount of N (e.g., dilute nitride) is added to a GaAs based compound. For example, referring to FIG. 4, when a small amount of N is added to GaAs, GaAsN is formed, wherein GaAsN has a lower band gap energy than GaAs.

The multijunction solar cell 500 uses the principle that GaIn(N)As, wherein which GaAsN and InGaAs are mixed, may adjust its band gap energy and lattice constant according to its composition. For instance, as the N content increases, the lattice constant of GaAsN may decrease more than the lattice constant of GaAs so that GaIn(N)As, in which GaAsN and InGaAs are mixed, may be selected in the slanted lines region illustrated in FIG. 4 so as to compensate for the strain caused by GaAs. The band gap energy of the GaIn(N)As selected in the slanted lines region may be in the range of about 0.7 to about 1.4 eV, and the lattice constant of GaIn(N)As may be greater than that of GaAsN so as to offset the strain generated by GaAsN.

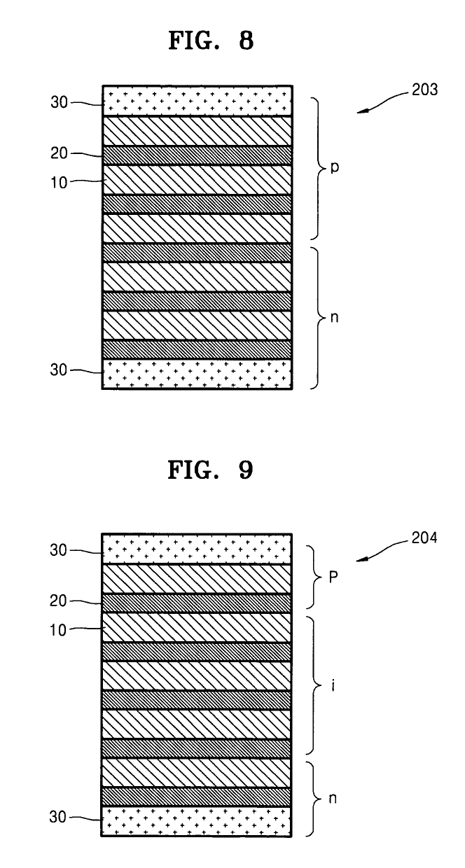

FIG. 5 is a diagram illustrating the GaAsN sub cell of FIG. 2 compensating for strain. Compressive strain may be generated in GaAsN, which has a smaller lattice constant than that of Ge. GaIn(N)As may be selected to have a larger lattice constant than that of GaAsN. As a result, tensile strain may be generated in GaIn(N)As. The N content of GaIn(N)As may be adjusted to appropriately offset the strain generated by GaAsN, and a thickness of GaIn(N)As may also be adjusted. For example, as the lattice constant of GaIn(N)As increases, offsetting of the strain caused by GaAsN is possible by adjusting the thickness of the GaIn(N)As to be smaller. Because the GaIn(N)As and GaAsN are alternately stacked, the compressive strain and the tensile strain in each stacked layer offset each other, thereby reducing or preventing the occurrence of crystalline defects and/or cracks.

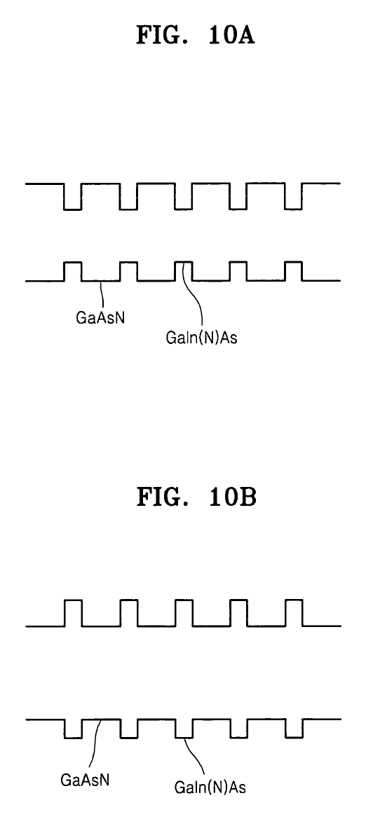

FIGS. 6 through 9 are cross sectional views of various examples of GaAsN sub cells 201 to 204 that may be employed in the multijunction solar cell 500 of FIG. 1. Referring to FIG. 6, the GaAsN sub cell 201 has a p-n junction structure. In the GaAsN sub cell 201, a p structure, in which first layers 10 formed of p-GaAsN and second layers 20 formed of p-GaIn(N)As are alternately stacked, is combined with an n structure, in which first layers 10 formed of n-GaAsN and second layers 20 formed of n-GaIn(N)As are alternately stacked.

Referring to FIG. 7, the GaAsN sub cell 202 has a p-i-n junction structure. In the GaAsN sub cell 202, GaAsN/GaIn(N)As, formed as a semiconductor intrinsic layer, is interposed between a p structure, in which first layers 10 formed of p-GaAsN and second layers 20 formed of p-GaIn(N)As are alternately stacked, and an n structure, in which first layers 10 formed of n-GaAsN and second layers 20 formed of n-GaIn(N)As are alternately stacked.

Referring to FIG. 8, the GaAsN sub cell 203 has a p-n junction structure similar to that of FIG. 6. However, the GaAsN sub cell 203 includes GaAs layers 30 as cladding layers. The GaAs layers 30 may be the uppermost layer and the lowermost layer of the GaAsN sub cell 203. The GaAs layers 30 may have relatively high band gap energies. These cladding layers, also known as windows or back surface field (BSF), may be used to efficiently confine carriers and may be formed of GaAs, AlGaAs, or InGaAlP.

Referring to FIG. 9, the GaAsN sub cell 204 has a p-i-n junction structure that is similar to that of FIG. 7. However, as in FIG. 8, the GaAsN sub cell 204 includes GaAs layers 30 as cladding layers having relatively high band gap energies.

The GaAs layers 30 may be the uppermost and lowermost layers of the GaAsN sub cell 204 and may be formed of GaAs, AlGaAs, or InGaAlP.

In the manufacture of the GaAsN sub cells 201 through 204, various Group III-V semiconductor material growing methods that are generally known may be used. For example, metal organic chemical vapor deposition (MOCVD), hydride vapor phase epitaxy (HYPE), molecular beam epitaxy (MBE), metal organic vapor phase epitaxy (MOVPE), and halide chemical vapor deposition (HCVD) may be used. Mg, Ca, Zn, Cd, or Hg may be used as a p-type dopant and Si may be used as an n-type dopant.

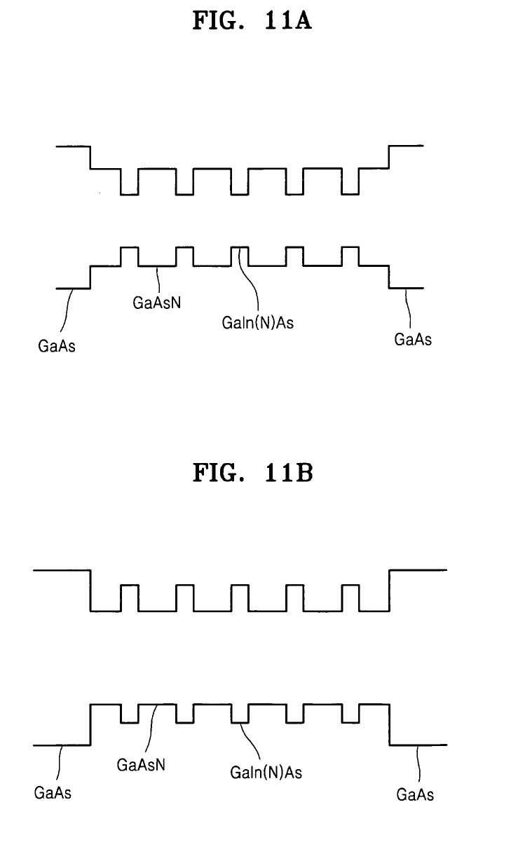

FIGS. 10A through 11B are band gap diagrams of the GaAsN sub cells 201 through 204. FIGS. 10A and 10B illustrate multi quantum well structures respectively showing when the band gap of GaAsN is smaller than that of GaIn(N)As and when the band gap of GaAsN is larger than that of GaIn(N)As. FIGS. 11A and 11B are similar to FIGS. 10A and 10B. However, GaAs layers may be disposed on the uppermost layer and the lowermost layer of the sub cells as illustrated in FIGS. 11A and 11B.

A multijunction solar cell according to example embodiments may employ sub cells having a structure in which GaAsN and GaIn(N)As are alternately stacked. As a result, the occurrence of crystalline defects may be relatively low and photoelectrical conversion efficiency may be relatively high.

While example embodiments have been disclosed herein, it should be understood that other variations may be possible. Such variations are not to be regarded as a departure from the spirit and scope of example embodiments of the present application, and all such modifications as would be obvious to one skilled in the art are intended to be included within the scope of the following claims.

What is claimed is:

1. A multijunction solar cell comprising:
a plurality of sub cells, each sub cell having a different band gap energy,
wherein at least one of the plurality of sub cells is a GaAsN sub cell having alternately stacked first layers and second layers, the first layers formed of GaAsₓN₁₋ₓ (0<x<1) and the second layers formed of GaₓIn₁₋ₓN_{y}As_{1-y} (0<x≦1, 0≦y<1).

2. The multijunction solar cell of claim 1, wherein the second layers are formed of GaₓIn₁₋ₓN_{y}As_{1-y} (0<x<1, 0≦y<0.5).

3. The multijunction solar cell of claim 1, wherein the N constituent of GaₓIn₁₋ₓN_{y}As_{1-y} (0<x<1, 0≦y<1) provides a lattice constant for offsetting strain caused by the GaAsₓN₁₋ₓ (0<x<1).

4. The multijunction solar cell of claim 1, wherein the band gap energy of GaₓIn₁₋ₓN_{y}As_{1-y} (0<x<1, 0≦y<1) and the band gap energy of GaAsₓN₁₋ₓ (0<x<1) form a multi quantum well structure, the band gap energy of GaₓIn₁₋ₓN_{y}As_{1-y} (0<x<1, 0≦y<1) being higher than the band gap energy of GaAsₓN₁₋ₓ (0<x<1).

5. The multijunction solar cell of claim 1, wherein the band gap energy of GaₓIn₁₋ₓN_{y}As_{1-y} (0<x<1, 0≦y<1) and the band gap energy of GaAsₓN₁₋ₓ (0<x<1) form a multi quantum well structure, the band gap energy of GaₓIn₁₋ₓN_{y}As_{1-y} (0<x<1, 0≦y<1) being lower than the band gap energy of GaAsₓN₁₋ₓ(0<x<1).

6. The multijunction solar cell of claim 1, wherein the GaAsN sub cell has a thickness of about 0.1 um to about 5 um.

7. The multijunction solar cell of claim 1, wherein the plurality of sub cells is four or more.

8. The multijunction solar cell of claim 1, wherein
the plurality of sub cells include a first sub cell formed of Ge, and
the GaAsN sub cell is a second sub cell disposed on the first sub cell.

9. The multijunction solar cell of claim 8, further comprising:
a sub cell formed of InₓGa₁₋ₓAs (0<x<1), InₓGa₁₋ₓP (0<x<1), In_{1-x-y}GaₓAl_{y}P (0≦x<1, 0≦y<1, 0≦x+y<1), AlₓGa₁₋ₓAs (0<x≦1), or combinations thereof on the GaAsN sub cell.

10. The multijunction solar cell of claim 8, further comprising:
a third sub cell formed of InₓGa₁₋ₓAs (0<x<1) on the GaAsN sub cell.

11. The multijunction solar cell of claim 10, further comprising:
a fourth sub cell formed of InₓGa₁₋ₓP (0<x<1) on the third sub cell.

12. The multijunction solar cell of claim 11, wherein the N constituent of GaₓIn₁₋ₓN_{y}As_{1-y} (0<x<1, 0≦y<1) provides a lattice constant for offsetting strain caused by the GaAsₓN₁₋ₓ (0<x<1).

13. The multijunction solar cell of claim 11, wherein the band gap energy of GaₓIn₁₋ₓN_{y}As_{1-y} (0<x<1, 0≦y<1) and the band gap energy of GaAsₓN₁₋ₓ (0<x<1) form a multi quantum well structure, the band gap energy of GaₓIn₁₋ₓN_{y}As_{1-y} (0<x<1, 0≦y<1) being higher than the band gap energy of GaAsₓN₁₋ₓ (0<x≦1).

14. The multijunction solar cell of claim 11, wherein the band gap energy of GaₓIn₁₋ₓN_{y}As_{1-y} (0<x<1, 0≦y<1) and the band gap energy of GaAsₓN₁₋ₓ (0<x<1) form a multi quantum well structure, the band gap energy of GaₓIn₁₋ₓN_{y}As_{1-y} (0<x<1, 0≦y<1) being lower than the band gap energy of GaAsₓN₁₋ₓ (0<x<1).

15. The multijunction solar cell of claim 11, wherein the GaAsN sub cell has a thickness of about 0.1 um to about 5 um.

16. The multijunction solar cell of claim 1, wherein the GaAsN sub cell has a p-n junction structure.

17. The multijunction solar cell of claim 16, further comprising:
cladding layers formed of GaAs, AlGaAs, or InGaAlP on an uppermost layer and a lowermost layer of the GaAsN sub cell.

18. The multijunction solar cell of claim 1, wherein the GaAsN sub cell has a p-i-n junction structure.

19. The multijunction solar cell of claim 18, further comprising:
cladding layers formed of GaAs, AlGaAs, or InGaAlP on an uppermost layer and a lowermost layer of the GaAsN sub cell.
